(19) United States
(12) Patent Application Publication
(10) Pub. No.: US 2009/0014869 A1
(43) Pub. Date: Jan. 15, 2009

(54) SEMICONDUCTOR DEVICE PACKAGE WITH BUMP OVERLYING A POLYMER LAYER

(76) Inventors: Joan K. Vrtis, Mesa, AZ (US); Anthony Curtis, Gilbert, AZ (US); Bret Trimmer, Mesa, AZ (US); Brian King, Gilbert, AZ (US); Yuan Lu, Phoenix, AZ (US); Haluk Balkan, Phoenix, AZ (US)

Correspondence Address: GREENBERG TRAURIG LLP (LA), 2450 COLORADO AVENUE, SUITE 400E, INTELLECTUAL PROPERTY DEPARTMENT, SANTA MONICA, CA, 90404, US

(21) Appl. No.: 11/718,192

(22) PCT Filed: Oct. 28, 2005
(86) PCT No.: PCT/US05/39008

§ 371 Date: Dec. 5, 2007

Related U.S. Application Data
(60) Provisional application No. 60/623,200, filed on Oct. 29, 2004.

(51) Int. Cl. H01L 23/488; H01L 21/44

(52) U.S. Cl. 257/737; 438/613; 257/E21.476; 257/E23.023

(57) ABSTRACT

A semiconductor device package, for example a flip-chip package, having a solder bump mounted above a polymer layer for use in flip-chip mounting of a semiconductor device to a circuit board. A polymer layer such as polybenzoxazole is formed overlying a wafer passivation layer. Solder bumps are attached to an under-bump metallization layer and electrically coupled to conductive bond pads exposed by openings in the wafer passivation layer.

### RELATED APPLICATION

This application is a non-provisional application claiming benefit under 35 U.S.C. sec. 119(e) of U.S. Provisional Application Ser. No. 60/623,200, filed Oct. 29, 2004 (titled HIGH PERFORMANCE CHIP SCALE PACKAGE FOR RADIO FREQUENCY DEVICES by Joan K. Vrtis et al.), which is incorporated by reference herein.

### FIELD

The present disclosure generally relates to a structure and method for semiconductor devices, and more particularly to a structure and method for a semiconductor device having a solder bump mounted above a polymer layer for use in, for example, flip-chip mounting of a semiconductor radio frequency device to a circuit board.

### BACKGROUND

In wafer level packaging (WLP) and flip-chip packaging, the redistribution of electrical signals from one portion of a semiconductor device to another portion for electrically coupling to a solder bump has traditionally been accomplished through the use of metal runners or redistribution traces and a dielectric passivation layer such as benzocyclobutene (BCB) or a polyimide. Under-bump metallization (UBM) layers are sometimes used on top of these runners in the solder bump pad for a solder bump. These runners and UBM layers have been composed of various combinations of aluminum, copper, titanium and vanadium-doped nickel, and in other cases of chrome and copper.

The materials used in the existing metal runners and UBM layers above have limited electrical properties (e.g., dielectric characteristics) and mechanical properties (e.g., poor adhesion, low fracture toughness, and low elongation), which often negatively impact the package performance and integrity for higher frequency applications (e.g., radio frequency devices operating at frequencies greater than about 1 MHz). For example, in radio-on-chip applications both the mechanical and electrical properties of the polymer passivation must be balanced to achieve optimum performance and reliability.

The poor adhesion properties of BCB to the metals used in prior runners as well as cracking that may result from its low fracture toughness necessitates that the endpoint of each runner rest directly on the wafer passivation layer (e.g., silicon nitride) to provide an adequate mechanical anchor. Without this anchoring, the mechanical performance and integrity of the package is not sufficient for many applications. Also, BCB's low fracture toughness and its poor adhesion to UBM layers in prior packages has limited package integrity as exhibited by metal failure at the solder-metal interface (e.g., bump structure lift-off from the BCB) and reliability failures during temperature cycling.

A resulting disadvantage of using the wafer passivation layer as an anchor is the close proximity of the solder bump to the integrated circuit in the underlying semiconductor wafer. When packaging a device for use in a radio frequency application, this close proximity leads to interference of electrical signals transmitted through the redistribution trace and the solder bump with the integrated circuit, especially at higher frequencies.

Accordingly, it would be desirable to have an improved semiconductor package and method that provides improved electrical and mechanical performance for radio frequency applications.

### BRIEF DESCRIPTION OF THE DRAWINGS

For a more complete understanding of the present disclosure, reference is now made to the following figures, wherein like reference numbers refer to similar items throughout the following figures:

FIG. 1 illustrates a cross-sectional view of a portion of a semiconductor wafer used to form a redistributed chip scale packaged integrated circuit according to a first exemplary embodiment of the present disclosure.

FIG. 2 illustrates a cross-sectional view of a portion of a semiconductor wafer used to form a bump-on-I/O chip scale packaged integrated circuit, according to a second exemplary embodiment of the present disclosure, in which the polymer layer is outside of the wafer passivation layer.

FIG. 3 illustrates a top perspective view for the bump-on-I/O chip scale package of FIG. 2 prior to the formation of the UBM layer thereon.

FIG. 4 illustrates a top perspective view for the bump-on-I/O chip scale package of FIG. 2 after the formation of the UBM layer thereon.

FIG. 5 illustrates a cross-sectional view of a portion of a semiconductor wafer used to form a bump-on-I/O chip scale packaged integrated circuit, according to a third exemplary embodiment of the present disclosure, in which the polymer layer is inside of the wafer passivation layer.

FIGS. 6A-6E illustrate cross-sectional views of a process to fabricate the chip scale package of FIG. 1 according to an exemplary embodiment of the present-disclosure.

The exemplification set out herein illustrates particular embodiments, and such exemplification is not intended to be construed as limiting in any manner.

### DETAILED DESCRIPTION

The following description and the drawings illustrate specific embodiments sufficiently to enable those skilled in the art to practice the systems and methods described herein. Other embodiments may incorporate structural, logical, process and other changes. Examples merely typify possible variations.

The elements that implement the various embodiments of the present system and method are described below. Many elements may be configured using well-known structures. It should also be understood that the techniques of the present system and method might be implemented using a variety of technologies.

The disclosure of specific embodiments of a semiconductor device package having solder bumps disposed overlying a polymer layer and a method therefor is now presented below. The semiconductor device package is typically implemented as a chip scale package or a wafer level package, for example, as used for chip-on-board assembly applications or as a standard flip-chip package used in flip-chip package applications. Examples of such implementations are described in U.S. Pat. No. 6,441,487 (titled Chip Scale Package Using Large Ductile Solder Balls by Elenius et al. issued Aug. 27, 2002) and U.S. Pat. No. 5,844,304 (titled Process for Manufacturing Semiconductor Device and Semiconductor Wafer by Kata et al. issued Dec. 1, 1998), and U.S. Pat. No. 5,547,740 (titled Solderable Contacts for Flip Chip Integrated Circuit Devices by Higdon et. al. issued Aug. 20, 1996) and U.S. Pat. No. 6,251,501 (titled Surface Mount Circuit Device and Solder Bumping Method Therefor by Higdon et al. issued Jun. 26, 2001) which are each hereby incorporated by reference at least for their teachings regarding packaging applications, structures and fabrication methods.

Redistributed Structure

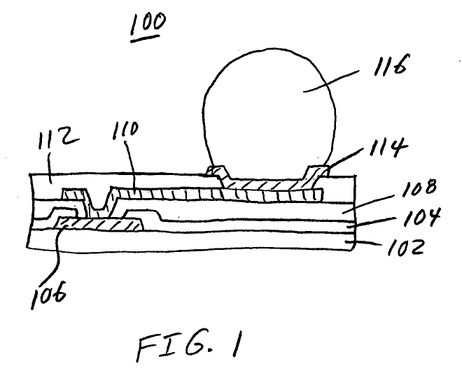

FIG. 1 illustrates a cross-sectional view of a portion of a semiconductor wafer used to form a redistributed chip scale package 100. More specifically, an integrated circuit (not shown) is formed on a front surface of semiconductor substrate 102. A conductive bond pad 106 is formed at the front surface to make electrical connections to the integrated circuit. A typical package 100 will include a large number of bond pads 106. Semiconductor substrate 102 is typically silicon. It should be noted, however, that although substrate 100 is described here as being formed from a semiconductor material, in other embodiments other semiconductor and non-semiconductor materials may be used such as, for example, GaAs, glass, saphire, SiGe, quartz, and LiTaO₃.

Wafer passivation layer 104 has an opening to expose a portion of bond pad 106 for electrical connection to conductive layer 110. Polymer layer 108 is formed on wafer passivation layer 104 and has an opening to permit electrical connection of conductive layer 110 to a central portion of pad 106. In other embodiments, conductive layer 110 may contact peripheral or other portions of pad 106. In the redistributed structure of package 100, conductive layer 110 is a redistribution trace or runner used to permit solder bump 116 to be positioned varying distances away from pad 106 (i.e., solder bump 116 is not positioned above pad 106) as described, for example, in U.S. Pat. No. 6,441,487 above. Redistribution trace 110 may be, for example, formed using an Al/Ni/Cu/Ti stack. The titanium may be formed on the bottom of the stack in other embodiments. Titanium is desirably selected to provide good adhesion to the polymer used in polymer layer 108. Titanium also may aid in reducing electromigration resulting from corrosion. Redistribution trace 110 may have a thickness, for example, of about 1 micron or greater (e.g., about 3 microns).

Wafer passivation layer 104 may be, for example, a polymer or other material suitable for wafer passivation. Specific materials that may be used include, for example, silicon nitride, oxynitride, polyimide, benzocyclobutene, polybenzoxazole, or derivatives of polybenzoxazole. It should be noted in FIG. 1 that conductive layer 110 does not contact wafer passivation layer 104.

Conductive layer 110 and UBM layer 114 are used to provide a solder bump pad to secure solder bump 116, which makes electrical connection to bond pad 106 through an opening in conductive layer 110. It should be noted that the structures and methods described herein may be used with a wide variety of solder bumps such as, for example, solder balls and other suitable known interconnect structures. Also, solder bump 116 may use a wide variety of known solder compositions.

Polymer layer 108 overlaps bond pad 106 by, for example, at least about 1 micron (e.g., about 2 microns). Polymer layer 108 has a thickness of, for example, greater than about 1 micron, or more specifically greater than about 3 microns. An increased thickness of polymer layer 108 aids in reducing negative parasitic or electrical interference between conductive layer 110 and the integrated circuit on substrate 102.

Upper passivation layer 112 overlies conductive layer 110 and generally may be formed using one of the polymer materials described herein as suitable for use in polymer layer 108. Other suitable materials may also be used for upper passivation layer 112 such as, for example, passivation material sold by the Sumitomo Corporation under the trademark AVATREL. In many cases it is desirable that the material forming upper passivation layer 112 be substantially the same as the material forming polymer layer 108 so that mechanical stresses and cracking may be reduced. Upper passivation layer 112 may have a thickness, for example, of about 2 microns or greater.

Package 100 may be desirable for use in radio frequency applications, in particular for applications at frequencies greater than about 2.5 MHz (or even more particularly for frequencies greater than about 100 MHz), for which prior packages may exhibit significant signal degradation. Conductive layer 110 may be adapted to transmit electrical signals from the integrated circuit to an external circuit (not shown) electrically coupled to solder bumps 116 such that, for electrical signals having a frequency greater than, for example, about 1 MHz, effective transmission of the electrical signals is not prevented by electrical interference between the conductive layer and the integrated circuit. An exemplary frequency range for effective transmission is greater than about 2.5 MHz and less than about 1 GHz, which is a typical operating range for many FM and other radio transmitters (e.g., wireless transmitter/receivers configured for BLUETOOTH).

Polymer layer 108 is desirably formed of a polymer material having an elongation of greater than about 10%, and preferably greater than about 35%. The dielectric constant is preferably less than, for example, about 4.0. Polymer layer 108 may be, for example, formed using polybenzoxazole (PBO). Examples of suitable resin compositions for use in polymer layer 108 are described in U.S. Pat. No. 6,908,717 (titled Positive Photosensitive Resin Composition, Process for Its Preparation, and Semiconductor Devices by Hirano et al. issued Jun. 21, 2005), which is hereby incorporated by reference. Polymer layer 108 may also optionally contain various filler materials compatible with the one or more polymers used to form polymer layer 108.

Other polymers used for polymer layer 108 may include, for example, polyimide or a polyimide derivative. The material used to form polymer layer 108 is preferably resilient and exhibits good adhesion to the metal used at the interface surface to conductive layer 110 and to UBM layer 114.

UBM layer 114 may include, for example, aluminum, nickel, and copper. The nickel may be, for example, doped with vanadium. For example, UBM layer 114 may be formed as an Al/Ni/Cu stack. A titanium layer (not shown) may optionally be formed, for example, on the bottom surface of UBM layer 114. Other metal options for UBM layer 114 may include, for example, Ti(W)/Cu; Al/Electroless Ni/Immersion Au; Al/Electroless Ni/Pd/Au; AlCu/Electroless Ni/Immersion Au; AlCuSi/Electroless Ni/Immersion Au; and AlSi/Electroless Ni/Immersion Au. The thickness of UBM layer 114 may be, for example, about 1.0 microns or greater.

UBM layer 114 may overlap a portion of the top surface of upper passivation layer 112 by, for example, at least about 1 micron. An overlap distance sufficient to substantially seal UBM layer 114 over upper passivation layer 112 is preferred. Also, UBM layer 114 is typically greater in width than bond pad 106.

In other embodiments, UBM layer 114 may initially be designed with Ti as its top metal layer to support further processing, with this top metal layer being etched away to expose an underlying, for example, Cu layer of UBM layer 114 for solder bump attachment.

Bump-On-I/O Structure

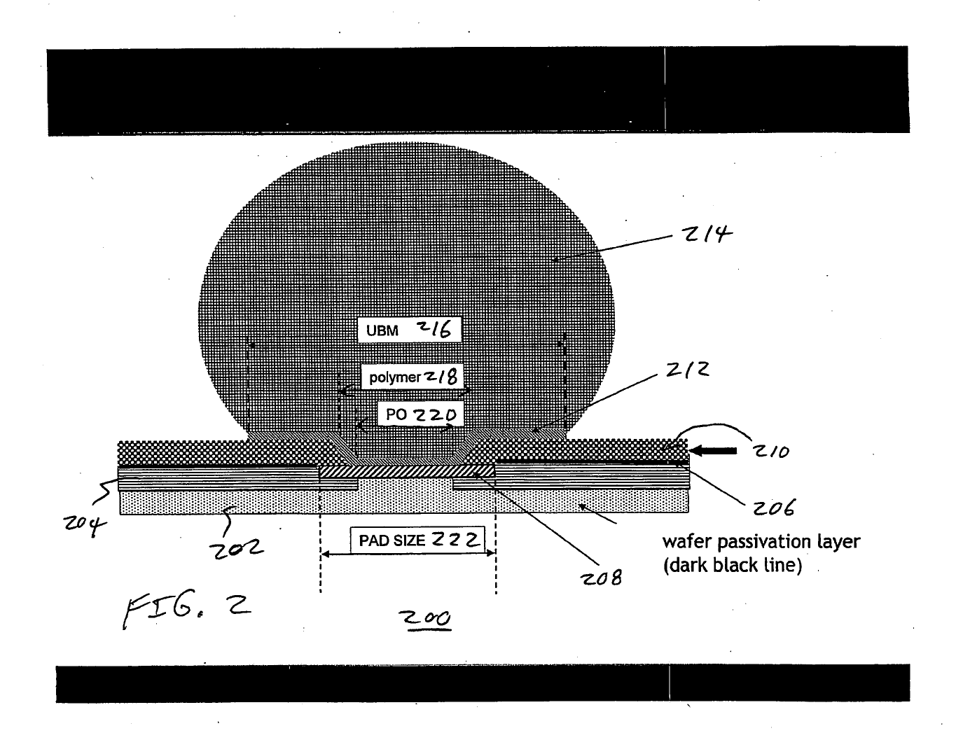

FIG. 2 illustrates a cross-sectional view of a portion of a semiconductor wafer used to form a bump-on-I/O chip scale package 200, in which polymer layer 210 is outside (i.e., extends beyond the edge) of wafer passivation layer 206. A bump-on-I/O structure is generally different from the re-distributed structure above in that the solder bump is not positioned completely away from the bond pad so that a redistribution layer substantially as described above is not required. However, the phrase “bump-on-I/O” is not intended to limit the practice of the presently-described structures to only those structures in which a solder bump is centered over a bond pad.

Semiconductor substrate 202 supports an integrated circuit (a portion thereof indicated by reference number 204). Substrate 202 may also be formed of non-semiconductor materials as described above for package 100. Bond pad 208 makes electrical connection to integrated circuit 204 and has a pad size 222. Package 200 may be adapted for suitable radio frequency usage similarly as described above for package 100.

UBM layer 212 has a width 216 and is in metal-to-metal contact with bond pad 208 at pad opening 220. Wafer passivation layer 206 has an opening to expose bond pad 208. Polymer layer 210 overlies wafer passivation layer 206. Wafer passivation layer 206, polymer layer 210, and UBM layer 212 may be formed using materials, thicknesses, and methods similar to those described for package 100 herein. For example, UBM layer 212 may be a Ti/vanadium-doped Ni/Cu stack or an Al/Ni/Cu/Ti stack. A titanium layer may also be formed, for example, on both the top and bottom surface of UBM layer 212.

Polymer layer 210 overlaps and contacts a portion of the top surface of conductive bond pad 208. This overlap may be, for example, at least about 1 micron, and alternatively at least about 2 microns. Polymer layer 210 has an opening 218 to permit UBM layer 212 to contact a central portion of bond pad 208.

Solder bump 214 is secured to UBM layer 212, which provides a solder bump pad for making electrical contact to bond pad 208. In general, at least a portion of solder bump 214 is positioned above bond pad 208 (FIG. 2 illustrates solder bump 214 substantially centered above bond pad 208, but offset positions are possible in other embodiments).

The bottom surface of UBM layer 212 generally makes contact to two types of surfaces: the metal surface of bond pad 208, and the polymer surface of polymer layer 210. According to this embodiment, greater than about 50% of the bottom surface area of UBM layer 212 is overlying and in contact with polymer layer 210, and alternatively greater than about 70%. As is typically desirable, the portion of UBM layer 212 in metal-to-metal contact with its respective bond pad 208 is less than about 30% of the total bottom surface area of UBM layer 212, and alternatively less than about 15%. For example, the width of a square-shaped metal-to-metal contact area may be, for example, about 35 microns, or even about 10 microns.

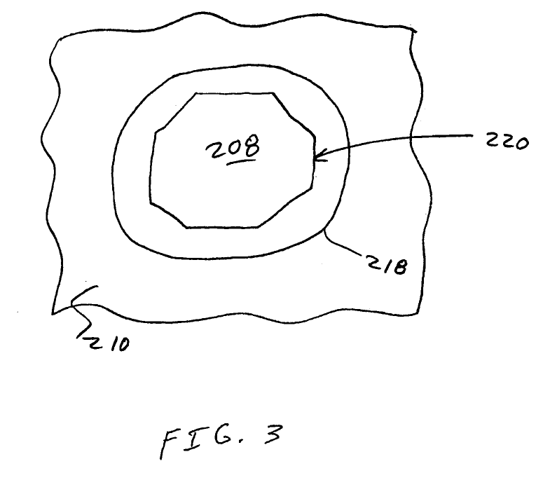

FIG. 3 illustrates a top perspective view for the bump-on-I/O chip scale package 200 prior to the formation of UBM layer 212. A portion of bond pad 208 is exposed through pad opening 220. Opening 218 in polymer layer 210 is provided so that bond pad 208 may make contact to UBM layer 212.

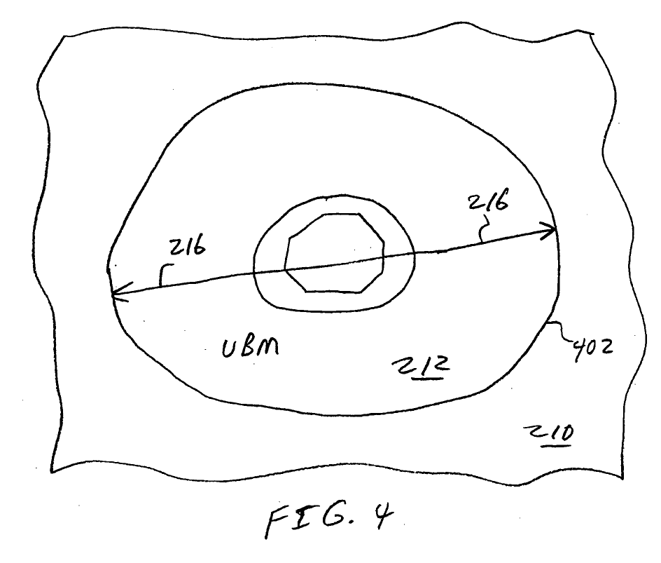

FIG. 4 illustrates a top perspective view for the bump-on-I/O chip scale package 200 after the formation of a patterned UBM layer 212 across the surface of package 200. As shown in FIG. 4, the portion of patterned UBM layer 212 that contacts one of the conductive bond pads 208 of package 200 may be, for example, substantially symmetrical about the central portion of the bond pad. The outer perimeter 402 of the shape of the portion of patterned UBM layer 212 shown here is substantially circular with a diameter or width 216. However, in other embodiments other shapes such as a rectangle or oval may be used, and the UBM layer portion need not be centered or symmetrical about bond pad 208. Width 216 may be, for example, greater than about 150 microns.

In general, it should be noted that the UBM layer and/or the bond pad of the structures described herein may have varying shapes. In the case of a circle, references to “width” herein mean the diameter of such shape, and in the case of a rectangle, the shorter of the two rectangular dimensions of such shape.

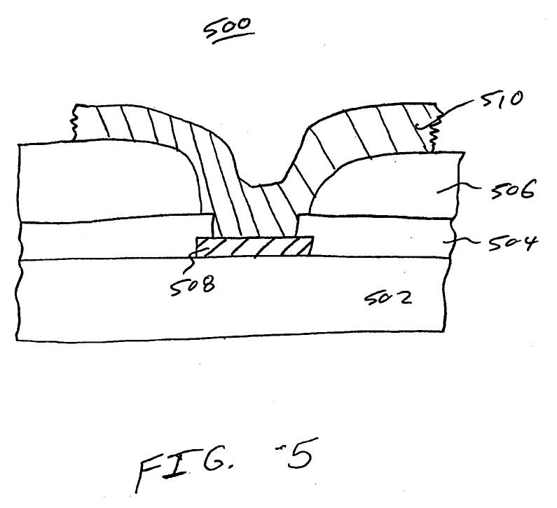

FIG. 5 illustrates a cross-sectional view of a portion of a semiconductor wafer used to form a bump-on-I/O chip scale package 500 in which polymer layer 506 is inside (i.e., does not extend beyond the edge) of wafer passivation layer 504. Package 500 is substantially similar in structure and manufacture to package 200 above. For example, the structure of UBM layer 510 may be substantially the same as that used for UBM layer 212 above.

Conductive bond pad 508 is formed at the front surface of semiconductor substrate 502. Polymer layer 506 is formed overlying wafer passivation layer 504. UBM layer 510 makes electrical contact to bond pad 508 through an opening in polymer layer 506.

Processing

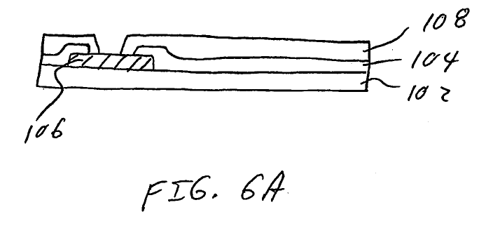

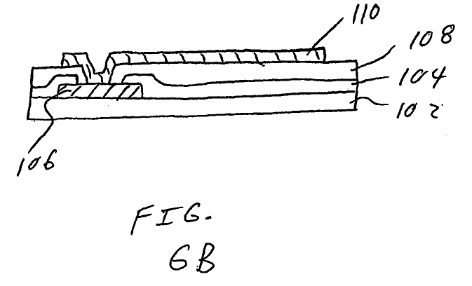

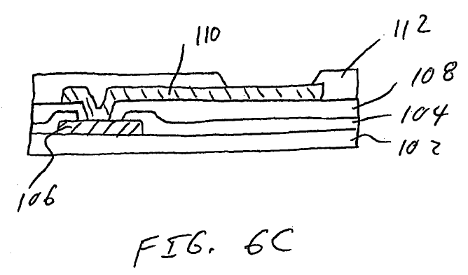

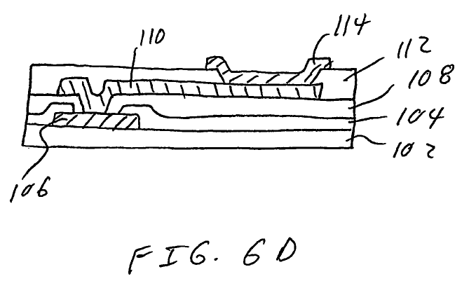

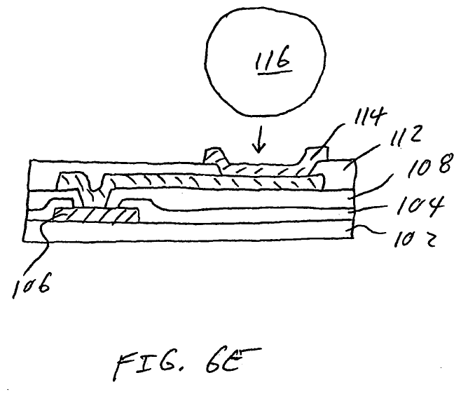

FIGS. 6A-6E illustrate cross-sectional views of an exemplary process to fabricate; package 100 of FIG. 1. Other processes may be used in other embodiments. The process attributes below are provided as a specific, non-limiting example for a wafer level package or standard flip-chip implementation. Packages 200 and 500 may be formed, for example, using similar processing steps to those described below for package 100.

In FIG. 6A, conductive bond pads 106 are formed on semiconductor substrate 102 using a conventional process. Wafer passivation layer 104 is formed using a conventional process over the front surface of substrate 102 to have openings to expose a portion of conductive bond pads 106.

Next, polymer layer 108 is formed by coating, for example, PBO over wafer passivation layer 104 to a thickness of at least about 3 microns (e.g., 4 or 5 microns). The thickness may vary based on the application. The polymer used in polymer layer 108 desirably has material properties that help compensate for inherent stress in package 100. Polymer layer 108 is used as a planarizing dielectric to passivate the die surface. Polymer layer 108 is baked, exposed, and developed to pattern it. Polymer layer 108 is then partially cured in an inert environment, which is believed to aid in reducing residual stresses and film oxidation.

In FIG. 6B, redistribution traces 110 are formed by deposition of, for example, a Ti/Al/Ti stack using sputtering or other metal deposition techniques. The deposited layer is patterned and etched to form traces 110 and an area for the solder bump pad. Prior to this metal deposition, it is desirable to clean the top surface of polymer layer 108 using, for example, a plasma or a chemical rinse.

In the Ti/Al/Ti stack above, the first Ti layer is preferably equal to or greater than about 1,000 Angstroms to act as an adhesion layer to polymer layer 108. The Al layer is preferably equal to or greater than about 10,000 Angstroms and acts as the main electrical signal carrier to and from solder bump 116. The second Ti layer is preferably equal to or greater than about 1,000 Angstroms to act as a corrosion barrier due to titanium's high corrosion resistance. In general, a ratio of about 10:1 (aluminum layer thickness to Ti layer thickness) is desirable.

In FIG. 6C, upper passivation layer 112 is formed by coating, for example, a PBO polymer over the surface of redistribution traces 110 and polymer layer 108. The polymer is exposed, patterned, developed and cross-linked to passivate the surface of the device and protect the redistribution traces 110 and to form openings for solder bump pads on redistribution traces 110. The thickness of upper passivation layer 112 is preferably greater than about 4 microns. Upper passivation layer 112 is preferably cured in an inert environment to help provide resistance to chemical, heat and moisture conditions in later processing.

In FIG. 6D, UBM layer 114 is formed by depositing an Al/NiV/Cu stack. The metal may be, for example, deposited using a single step process with a multiple chamber sputtering tool (i.e., one chamber as a source for each metal to be deposited starting with Al, then followed by NiV and Cu). UBM layer 114 may also contain a Ti layer for its desirable adhesion to polymer layer 108. The use of titanium may also provide improved corrosion resistance to the outside environment. The metal layer is patterned to form the final UBM layer 114 for attachment to a solder bump.

In FIG. 6E, solder bumps 116 are mounted to their respective patterned portions of UBM layer 114. In wafer level packaging, a pre-formed solder sphere may be used as the interconnect material. In this process example, a pre-formed solder bump 116 is placed onto UBM layer 114. Solder bump 116 may then be adhered using standard reflow processing. In other embodiments, solder bumps 116 may be formed using standard solder plating or solder paste techniques.

The processing steps described above are typically performed at the wafer level (i.e., before the semiconductor wafer is diced to form individual integrated circuits or chip scale packages). However, in other embodiments, some or all of the processing steps used to form the chip scale package may be performed after the semiconductor wafer is diced. After the semiconductor wafer is diced, the individual chip scale packages may be mounted, for example, to a circuit board or other patterned substrate.

### CONCLUSION

By the foregoing disclosure, an improved apparatus and method for a semiconductor device package have been described. The package and method above may help reduce or eliminate reliability issues such as electromigration, and lack of adhesion between the UBM layer, the redistribution traces and the polymer system used in wafer level and flip-chip packaging. The package and method may also provide enhanced electrical properties for radio device applications. The package and method of the present disclosure may be useful in a variety of applications including, for example, radio-on-chip devices (e.g., BLUETOOTH, FM radio devices, and devices based on other wireless protocols such as WiFi).

The package and method above may help achieve a broader design window for higher reliability, which may be aided, for example, by the use of a titanium interface with dielectric re-passivation and redistribution polymers, and/or by the use of titanium/aluminum/titanium redistribution runners with optimized geometries for width and thickness to achieve both desirable low and high frequency electrical performance. The temperature cycle reliability of the package also may exceed that of prior chip scale packages.

Although specific exemplary apparatuses and methods were described above, one of skill in the art will recognize that in other embodiments many of the above steps may be re-arranged and/or omitted. The foregoing description of specific embodiments reveals the general nature of the disclosure sufficiently that others can, by applying current knowledge, readily modify and/or adapt it for various applications without departing from the generic concept. For example, additional polymer layers and redistribution traces could be used to form multiple layers of metal (e.g., up to five layers) above the semiconductor wafer. Therefore, such adaptations and modifications are within the meaning and range of equivalents of the disclosed embodiments. The phraseology or terminology employed herein is for the purpose of description and not of limitation.

1. A semiconductor device comprising:
a substrate having an integrated circuit formed on a front surface of the substrate and a plurality of conductive bond pads formed at the front surface for making electrical interconnections to the integrated circuit;
a wafer passivation layer on the front surface of the substrate, wherein the wafer passivation layer has openings to expose at least a portion of the conductive bond pads;
a polymer layer overlying the wafer passivation layer, wherein the polymer layer overlaps and contacts a portion of the top surface of the conductive bond pads and the polymer layer has openings to expose a central portion of the conductive bond pads;
a conductive layer positioned overlying and in contact with at least a portion of the polymer layer and providing a plurality of solder bump pads, wherein the conductive layer contacts the conductive bond pads through the openings in the polymer layer; and
a plurality of solder bumps, each being secured to a corresponding one of the solder bump pads.

2. The semiconductor device of claim 1 wherein the substrate is a semiconductor substrate.

3. The semiconductor device of claim 1 wherein the polymer layer overlaps the top surface of each of the conductive bond pads by at least about 1 micron.

4. The semiconductor device of claim 1 wherein the wafer passivation layer is formed of a material selected from the group consisting of: silicon nitride, oxynitride, polyimide, benzocyclobutene, polybenzoxazole, and derivatives of polybenzoxazole.

5. (canceled)

6. The semiconductor device of claim 1 wherein the polymer layer has a thickness of greater than about 2 microns and the conductive layer is adapted to transmit electrical signals from the integrated circuit to an external circuit electrically coupled to the solder bumps such that, for electrical signals having a frequency greater than about 1 MHz, effective transmission of the electrical signals is not prevented by electrical interference between the conductive layer and the integrated circuit.

7-8. (canceled)

9. The semiconductor device of claim 6 wherein the conductive layer comprises titanium.

10-11. (canceled)

12. The semiconductor device of claim 1 wherein each of the solder bump pads further comprises an under-bump metallization layer on the conductive layer for securing each of the solder bumps to its corresponding solder bump pad.

13. The semiconductor device of claim 12 further comprising an upper passivation layer overlying the conductive layer and wherein the under-bump metallization layer extends onto and overlaps a portion of the top surface of the upper passivation layer.

14. The semiconductor device of claim 13 wherein the under-bump metallization layer overlaps the portion of top surface of the upper passivation layer by at least about 1 micron.

15-19. (canceled)

20. The semiconductor device of claim 12 wherein the under-bump metallization layer comprises aluminum, nickel and copper.

21. The semiconductor device of claim 20 wherein the nickel is doped with vanadium.

22. The semiconductor device of claim 21 further comprising a titanium layer on the bottom surface or the top surface of the under-bump metallization layer.

23. The semiconductor device of claim 20 wherein the conductive layer comprises a titanium/aluminum/titanium stack.

24-25. (canceled)

26. The semiconductor device of claim 1 wherein the conductive layer is an under-bump metallization layer and wherein the under-bump metallization layer comprises one or more materials selected from the group consisting of: aluminum, nickel, copper, and titanium.

27-30. (canceled)

31. The semiconductor device of claim 1 wherein the polymer layer comprises polybenzoxazole.

32. (canceled)

33. The semiconductor device of claim 1 wherein the polymer layer has an elongation greater than about 10%.

34-43. (canceled)

44. A semiconductor device comprising:
a substrate having an integrated circuit formed on a front surface of the substrate and a plurality of conductive bond pads formed at the front surface for making electrical interconnections to the integrated circuit;
a wafer passivation layer on the front surface of the substrate, wherein the wafer passivation layer has openings to expose at least a portion of the conductive bond pads;
a polymer layer overlying the wafer passivation layer, wherein the polymer layer has openings to expose a central portion of the conductive bond pads;
an under-bump metallization layer overlying and in contact with the polymer layer, wherein the under-bump metallization layer contacts the conductive bond pads through the openings in the polymer layer;
a plurality of solder bumps, each being secured to a portion of the under-bump metallization layer; and
wherein each portion of the under-bump metallization layer securing one of the solder bumps has a bottom surface area and wherein less than about 30% of the bottom surface area is in metal-to-metal contact with its respective conductive bond pad.

45. The semiconductor device of claim 44 wherein less than about 15% of the bottom surface area is in metal-to-metal contact with its respective conductive bond pad.

46-47. (canceled)

48. The semiconductor device of claim 44 wherein each portion of the under-bump metallization layer securing one of the solder bumps has a bottom surface area and wherein greater than about 50% of the bottom surface area is in direct contact with the polymer layer.

49. (canceled)

50. The semiconductor device of claim 44 wherein the under-bump metallization layer comprises one or more materials selected from the group consisting of: aluminum, nickel, copper, and titanium.

51. (canceled)

52. The semiconductor device of claim 50 further comprising a titanium layer on the bottom surface or top surface of the under-bump metallization layer.

53-55. (canceled)

56. A semiconductor device comprising:
a substrate having an integrated circuit formed on a front surface of the substrate and a plurality of conductive bond pads formed at the front surface for making electrical interconnections to the integrated circuit;
a wafer passivation layer on the front surface of the substrate, wherein the wafer passivation layer has openings to expose at least a portion of the conductive bond pads;
a polymer layer overlying the wafer passivation layer, wherein the polymer layer overlaps and contacts a portion of the top surface of the conductive bond pads and has openings to expose a central portion of the conductive bond pads;
a patterned under-bump metallization layer overlying and in contact with the polymer layer, wherein the under-bump metallization layer comprises titanium and contacts the conductive bond pads through the openings in the polymer layer; and
a plurality of solder bumps, wherein at least a portion of each of the solder bumps is positioned above one of the conductive bond pads and secured to a portion of the under-bump metallization layer.

57. The semiconductor device of claim 56 wherein each portion of the under-bump metallization layer securing one of the solder bumps has a bottom surface area and wherein less than about 30% of the bottom surface area is in metal-to-metal contact with its respective conductive bond pad.

58. A method for forming a semiconductor device comprising a substrate having an integrated circuit formed on a front surface of the substrate and a plurality of conductive bond pads formed at the front surface for making electrical interconnections to the integrated circuit, the method comprising:
forming a wafer passivation layer on the front surface of the substrate with openings to expose at least a portion of the conductive bond pads;
forming a polymer layer overlying the wafer passivation layer, wherein the polymer layer overlaps and contacts a portion of the top surface of the conductive bond pads and the polymer layer has openings to expose a central portion of the conductive bond pads;
forming a conductive layer positioned overlying and in contact with at least a portion of the polymer layer and to provide a plurality of solder bump pads, wherein the conductive layer contacts the conductive bond pads through the openings in the polymer layer; and
mounting a plurality of solder bumps, each being secured to a corresponding one of the solder bump pads.

59-60. (canceled)
